(19) United States
(12) Patent Application Publication
(10) Pub. No.: US 2009/0090983 A1
(43) Pub. Date: Apr. 9, 2009

(54) DUAL WORK FUNCTION HIGH VOLTAGE DEVICES

(76) Inventors: James W. Adkisson, Jericho, VT (US); Jeffrey P. Gambino, Westford, VT (US); Edward J. Nowak, Essex Junction, VT (US); Steven H. Voldman, South Burlington, VT (US); Michael J. Zierak, Essex Junction, VT (US)

Correspondence Address: FREDERICK W. GIBB, III;Gibb Intellectual Property Law Firm, LLC, 2568-A RIVA ROAD, SUITE 304, ANNAPOLIS, MD, 21401, US

(21) Appl. No.: 11/866,594

(22) Filed: Oct. 3, 2007

(51) Int. Cl. H01L 29/78

(52) U.S. Cl. 257/409; 257/E29.255

(57) ABSTRACT

A transistor has a substrate having a channel region and source and drain regions within the substrate on opposite sides of the channel region. The structure includes a gate oxide above the channel region of the substrate and a gate conductor above the gate oxide. The polysilicon gate conductor comprises a source side positioned toward the source and a drain side positioned toward the drain. The source side comprises a first concentration of conductive doping and the drain side comprises a second concentration of the conductive doping that is less than the first concentration.

### BACKGROUND AND SUMMARY

The embodiments of the invention generally relate to field effect transistors and more particularly to high voltage field effect transistors that utilize very thin gate oxides and a dual sided gate conductor that accommodates such devices.

High voltage field effect transistors (HV FETs) sometimes use gate dielectrics which are to thin to reliably support the high voltages experienced by such devices. These high voltages need to be reduced in some way.

The invention disclosed herein uses an intrinsic or lightly doped gate polysilicon over the drain side of the device to increase poly depletion and thereby lower the field across the gate dielectric. The drain voltage (Vdrain) allowable on a long channel FET is limited by the gate-to-drain breakdown voltage (VBD). This gate-to-drain breakdown voltage is limited by the abilities of the gate dielectric. By increasing the gate polysilicon depletion, the embodiments herein allow the gate-to-drain breakdown voltage to increase. More specifically, during conduction, the lightly doped polysilicon gate helps accumulate carriers and lower the specific on resistance (Rspon) in the region under the lightly doped polysilicon. In the “off” state, the polysilicon will deplete and drop some voltage, allowing a higher gate-to-drain voltage (Vgd) than if the gate polysilicon were fully doped.

In one structural embodiment, the invention comprises a transistor that has a substrate having a channel region (e.g., P-well) and source and drain regions within the substrate on opposite sides of the channel region. The structure includes a gate oxide above the channel region of the substrate and a gate conductor (e.g., polysilicon) above the gate oxide.

One of the features of the inventive structure is that the polysilicon gate conductor comprises a source side positioned toward the source and a drain side positioned toward the drain. The source side comprises a first concentration of conductive doping (e.g., N-type) and the drain side comprises a second concentration of the conductive doping that is less than the first concentration. More specifically, the drain side of the gate conductor has at least some of the doping, but not as much as is used in the source side. Thus, the doping in the drain side is greater than zero, but less than the first concentration amount that is in the source side of the gate conductor.

The source side and the drain side of the polysilicon gate conductor each comprise approximately one-half of the length of the gate conductor that runs between the source and the drain. Also, the conductive doping can comprise the same or different material in the source side and the drain side of the polysilicon gate conductor. Further, the concentrations that are within the source side and drain side of the gate conductor are consistent throughout each of the respective sides.

These and other aspects of the embodiments of the invention will be better appreciated and understood when considered in conjunction with the following description and the accompanying drawings. It should be understood, however, that the following descriptions, while indicating embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIG. 1 is a schematic cross-sectional diagram of a transistor;

FIG. 2 is a schematic cross-sectional diagram of a transistor; and

FIG. 3 is a schematic cross-sectional diagram of a transistor.

### DETAILED DESCRIPTION OF EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

As mentioned above, high voltage field effect transistors (HV FETs) sometimes use gate dielectrics which are to thin to reliably support the high voltages experienced by such devices. In order to address these issues, the invention disclosed herein uses an intrinsic or lightly doped gate polysilicon over the drain side of the device to increase polysilicon depletion and thereby lower the field across the gate dielectric.

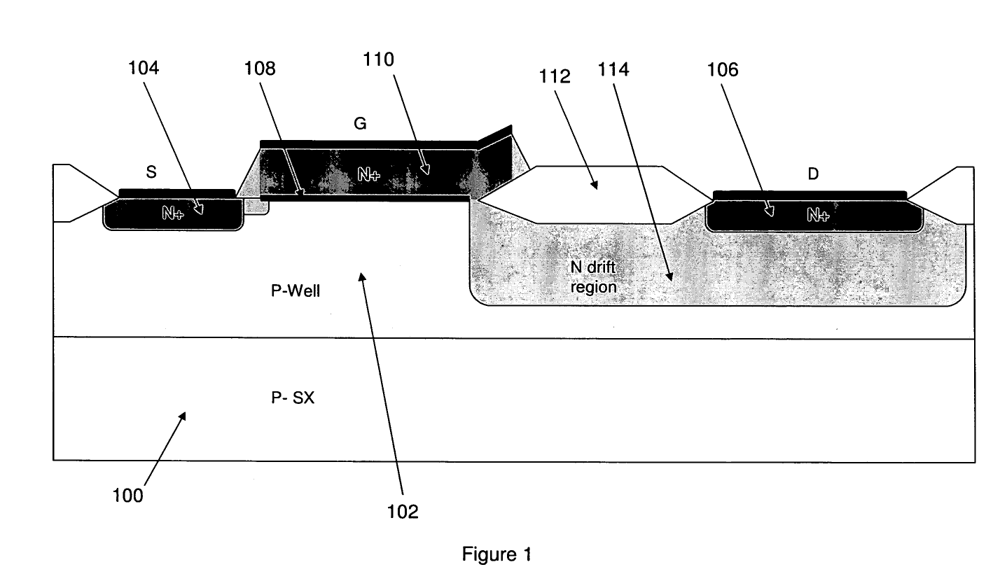

One field effect transistor, shown in FIG. 1, has a substrate 100 with a channel region 102 (e.g., P-well). Source 104 and drain 106 regions are within the substrate 100 on opposite sides of the channel region 102. The structure includes a gate oxide 108 above the channel region of the substrate and a gate conductor 110 (e.g., polysilicon) above the gate oxide. The source 104, drain 106, and gate 110 can be silicided to reduce resistance of each of these conductors.

The structure shown in FIG. 1 uses a local oxidation of silicon (LOCOS) process to create a LOCOS oxide region 112 between the gate conductor 110 and the drain 106. The oxide region 112 overlies a drift region 114. The drift region 114 reduces voltages that exist between the channel 102 and the gate conductor 110 by allowing charges to flow from the gate conductor 110 to the drain 106. Therefore, the drift region lowers voltages in the gate conductor 110 to a safe value across the dielectric 108. This drift region 114 can be an extended lightly doped drain (LDD) region which is unsilicided, or a deep implant that is below the field oxide or the shallow trench isolation region (STI).

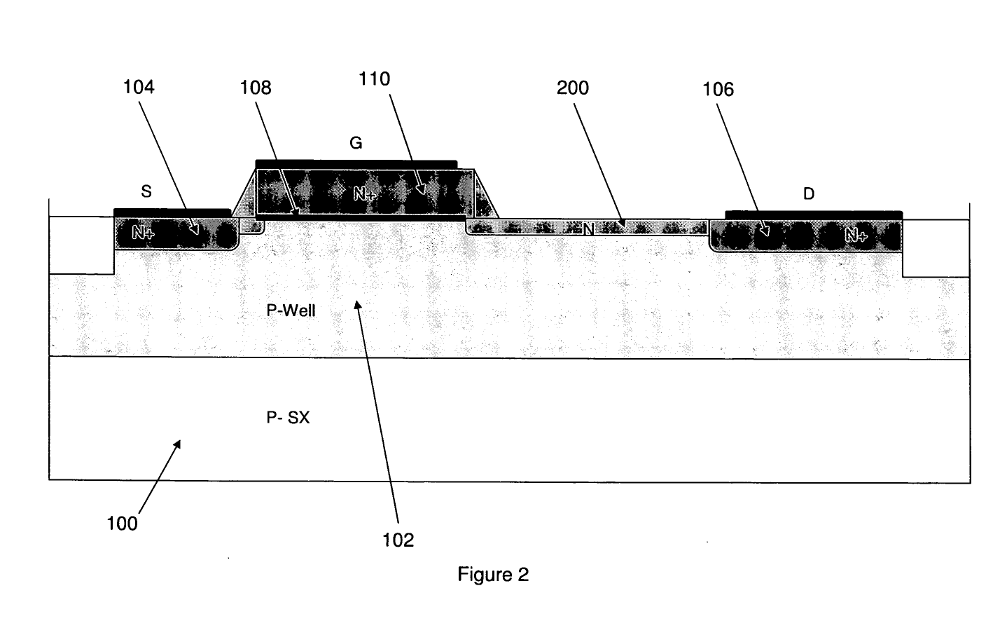

The structure shown in FIG. 2 is similar to that shown in FIG. 1, except that the transistor in FIG. 2 utilizes an unsilicided drain extension 200. Again, the excess charges can be dissipated from the gate conductor 110 to the drain 106 through the drain extension 200. However, such a structure produces a high specific on resistance (Rspon). The high on resistance of such a structure stems from the fact that doping in the extension 200 must be kept low to maintain the breakdown voltage at a high enough level. If the conductivity of the drain extension 200 were increased excessively, the breakdown voltage would fall to unacceptable levels.

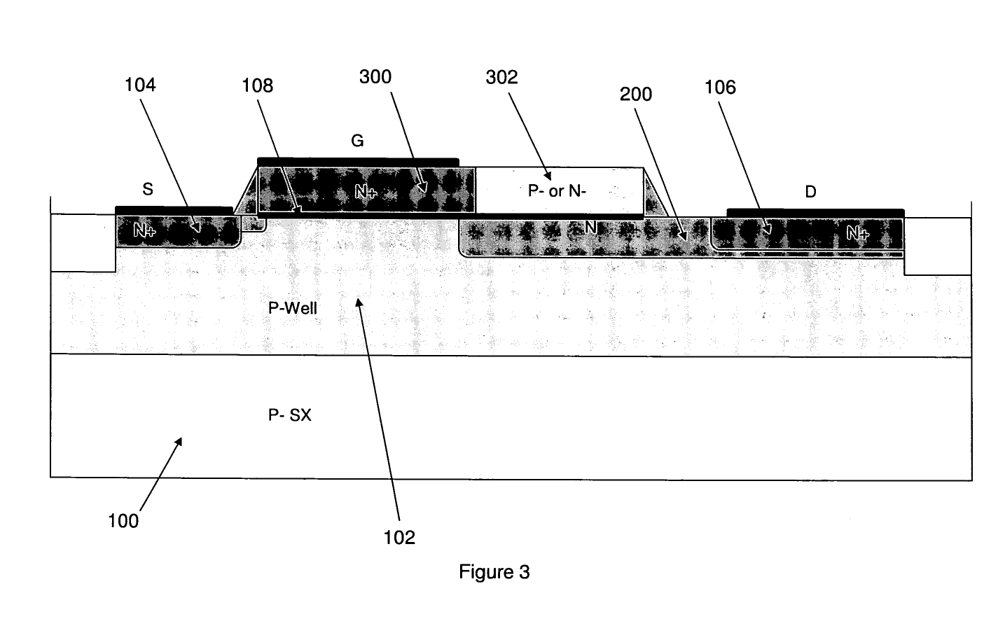

The structure shown in FIG. 3 achieves the same benefits of the structure shown in FIG. 2, without the high specific on resistance seen in the structure of FIG. 2. One of the features of the structure shown in FIG. 3 is that the polysilicon gate conductor comprises a source side 300 positioned toward the source 104 and a drain side 302 positioned toward the drain 106 and over the drain extension 200.

The source side 300 comprises a first concentration of conductive doping (e.g., high concentration N-type doping (N+)) and the drain side 302 comprises a second concentration of the conductive doping that is less than the first concentration (e.g., relatively low concentration P-type or relatively low concentration N-type doping (N− or P−)). More specifically, the drain side 302 of the gate conductor has at least some of the doping, but not as much as is used in the source side 300. Thus, the doping in the drain side 302 is greater than zero, but less than the first concentration amount that is in the source side 300 of the gate conductor. The lightly doped drain side of the gate conductor 302 depletes when the gate is off and the drain bias is high. This depleted region will support some of the gate to drain bias allowing for higher drain bias before dielectric breakdown occurs. Further, the low concentration doped drain side of the gate conductor 302 helps lower the specific on resistance (Rspon) when the gate conductor 300/302 is turned “On.”

The source side 300 and the drain side 302 of the gate conductor each comprise approximately one-half of the length of the gate conductor that runs between the source and the drain. Also, the conductive doping can comprise the same or different material in the source side 300 and the drain side 302 of the polysilicon gate conductor. Further, the concentrations that are within the source side 300 and drain side 302 of the gate conductor are consistent throughout each of the respective sides 300/302.

The drain voltage (Vdrain) allowable on a long channel FET is limited by the gate-to-drain breakdown voltage (VBD). This gate-to-drain breakdown voltage is controlled by the abilities of the gate dielectric. By increasing the gate polysilicon 300/302 depletion, the embodiments herein allow the gate-to-drain breakdown voltage to increase. More specifically, during conduction, the lightly doped polysilicon gate 302 helps accumulate carriers and lower the specific on resistance (Rspon) in the region under the lightly doped polysilicon. In the “off” state the drain side of the gate conductor 302 will deplete and drop some voltage, allowing a higher gate-to-drain voltage (Vgd) than if the gate were fully doped across its entire length.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of embodiments, those skilled in the art will recognize that the embodiments of the invention can be practiced with modification within the spirit and scope of the appended claims.

What is claimed is:

1. A transistor comprising:
a substrate having a channel region;
source and drain regions within said substrate on opposite sides of said channel region;
a gate oxide above said channel region of said substrate;
a gate conductor above said gate oxide,
wherein said gate conductor comprises a source side positioned toward said source and a drain side positioned toward said drain,
wherein said source side comprises a first concentration of conductive doping, and
wherein said drain side comprises a second concentration of said conductive doping that is greater than zero and less than said first concentration.

2. The method according to claim 1, all the limitations of which are incorporated by reference, wherein said source side and said drain side of said gate conductor each comprise approximately one-half of a length of said gate conductor that runs between said source and said drain.

3. The method according to claim 1, all the limitations of which are incorporated by reference, wherein said conductive doping comprises a same material in said source side and said drain side of said gate conductor.

4. A transistor comprising:
a substrate having a p-well channel region;
source and drain regions within said substrate on opposite sides of said channel region;
a gate oxide above said channel region of said substrate;
a polysilicon gate conductor above said gate oxide,
wherein said polysilicon gate conductor comprises a source side positioned toward said source and a drain side positioned toward said drain,
wherein said source side comprises a first concentration of N-type conductive doping, and
wherein said drain side comprises a second concentration of said N-type conductive doping that is greater than zero and less than said first concentration.

5. The method according to claim 4, all the limitations of which are incorporated by reference, wherein said source side and said drain side of said polysilicon gate conductor each comprise approximately one-half of a length of said gate conductor that runs between said source and said drain.

6. The method according to claim 4, all the limitations of which are incorporated by reference, wherein said N-type conductive doping comprises a same material in said source side and said drain side of said polysilicon gate conductor.
